(19) United States
(12) Patent Application Publication
(10) Pub. No.: US 2025/0318225 A1
(43) Pub. Date: Oct. 9, 2025

(54) SEMICONDUCTOR DEVICE AND METHOD FOR MANUFACTURING SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Takako MOTAI, Yokohama Kanagawa (JP); Yoko IWAKAJI, Meguro Tokyo (JP); Keiko KAWAMURA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/830,147

(22) Filed: Sep. 10, 2024

(30) Foreign Application Priority Data
Apr. 5, 2024 (JP) 2024-061617

(51) Int. Cl. H01L 29/32; H01L 21/22; H01L 29/40; H01L 29/861

(52) U.S. Cl. CPC H10D 62/53; H01L 21/221; H10D 8/422; H10D 64/117

(57) ABSTRACT

A semiconductor device includes a first electrode; a semiconductor layer located on the first electrode; and a second electrode located on the semiconductor layer. The semiconductor layer includes a first semiconductor layer including a rare-earth element, and a second semiconductor layer located on the first semiconductor layer and electrically connected with the second electrode, the second semiconductor layer contacting the first semiconductor layer. The first semiconductor layer includes an impurity region positioned between the second semiconductor layer and the first electrode, and a crystal defect region positioned between the impurity region and the first electrode. The crystal defect region includes crystal defects. A concentration peak of the rare-earth element is in the impurity region.

### CROSS-REFERENCE TO RELATED APPLICATION

This application is based upon and claims the benefit of priority from Japanese Patent Application No. 2024-061617, filed on Apr. 5, 2024; the entire contents of which are incorporated herein by reference.

### FIELD

Embodiments described herein relate generally to a semiconductor device and a method for manufacturing a semiconductor device.

### BACKGROUND

The power loss of a power semiconductor element is divided into conduction loss and switching loss based on function. Generally, there is a trade-off relationship between the conduction loss and the switching loss. It is particularly important to reduce the switching loss of a diode, and so lifetime control of the drift layer is often performed, which is problematic in that the forward voltage drop is simultaneously increased, thereby increasing the conduction loss.

### BRIEF DESCRIPTION OF THE DRAWINGS

FIG. 1 is a schematic cross-sectional view of a semiconductor device of a first embodiment;

FIG. 2 to FIG. 4 are schematic cross-sectional views showing a method for manufacturing the semiconductor device of the first embodiment;

FIG. 5 is a circuit diagram showing a configuration of a semiconductor device of a second embodiment;

FIG. 6 is a schematic cross-sectional view of a diode part of the semiconductor device of the second embodiment; and

FIG. 7 and FIG. 8 are schematic cross-sectional views showing a method for manufacturing the semiconductor device of the second embodiment.

### DETAILED DESCRIPTION

According to one embodiment, a semiconductor device includes a first electrode; a semiconductor layer located on the first electrode; and a second electrode located on the semiconductor layer, the semiconductor layer including a first semiconductor layer including a rare-earth element, the first semiconductor layer being of a first conductivity type, and a second semiconductor layer located on the first semiconductor layer and electrically connected with the second electrode, the second semiconductor layer contacting the first semiconductor layer, the second semiconductor layer being of a second conductivity type, the first semiconductor layer including an impurity region positioned between the second semiconductor layer and the first electrode, and a crystal defect region positioned between the impurity region and the first electrode, the crystal defect region including crystal defects, a concentration peak of the rare-earth element being in the impurity region.

Among the losses of a diode, the switching loss, i.e., the loss in reverse recovery, is more problematic than the conduction loss. To reduce the switching loss of a diode, it is effective to form a low-lifetime layer inside a semiconductor layer (the drift layer). The low-lifetime layer can reduce the switching loss by promoting recombination of carriers remaining inside the drift layer in reverse recovery. However, introducing the low-lifetime layer increases the forward voltage drop of the diode, which causes the conduction loss to increase. Therefore, continuing efforts are being made to find conditions that reduce the effects on the conduction loss.

Formation methods of the low-lifetime layer include Method 1, in which mainly an electron beam, H, He, or the like is irradiated, and Method 2, in which a deep level is made by doping a noble metal such as Au, Pt, etc. However, the lifetime layers formed by these methods are widely distributed in the depth direction, and so the lifetime of substantially the entire drift layer is reduced, and effects on the conduction loss are unavoidable. Moreover, in Method 1, low thermal and process stabilities require the irradiation to be performed at the final process of the element formation with a high acceleration voltage from the front surface and back surface of a thinned wafer. Therefore, a difficult and expensive backside process is necessary. An instability also is caused by effects of the light-element impurity density inside the wafer. In Method 2, the use of chemical elements having a large diffusion rate in silicon makes it impossible to locally form a low-lifetime layer in the planar direction as well as the depth direction. Therefore, when an IGBT (Insulated Gate Bipolar Transistor) and a diode are combined in one element to form an RC-IGBT (Reverse Conducting IGBT), there is a risk that the characteristics of the IGBT may be lost.

As described above, current lifetime control technology that promotes recombination of carriers by forming a low-lifetime layer inside the drift layer is effective for reducing the switching loss, but reduces the switching loss while substantially allowing the conduction loss to increase. Furthermore, the presence of many process constraints hinders cost reduction.

Exemplary embodiments will now be described with reference to the drawings. Similar components in the drawings are marked with like reference numerals. In the drawings below, directions are indicated by an X-axis, a Y-axis, and a Z-axis. A direction along the X-axis is taken as a first direction X. A direction along the Z-axis is taken as a second direction Z; and the second direction Z is orthogonal to the first direction X. A direction along the Y-axis is taken as a third direction Y; and the third direction Y is orthogonal to the first and second directions X and Z.

### First Embodiment

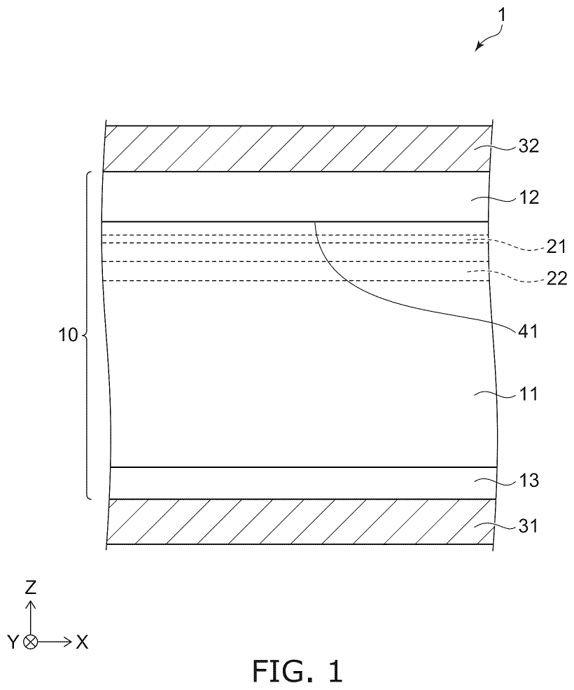

FIG. 1 shows a diode as a semiconductor device 1 of a first embodiment.

The semiconductor device 1 includes a first electrode 31, a second electrode 32, and a semiconductor layer 10 located between the first electrode 31 and the second electrode 32 in the second direction Z. The first electrode 31 is a cathode electrode of the diode; and the second electrode 32 is an anode electrode of the diode. A current flows in the vertical direction (the second direction Z) between the first electrode 31 and the second electrode 32 via the semiconductor layer 10. In the second direction Z, the direction from the first electrode 31 toward the second electrode 32 is taken as up or above, and the direction from the second electrode 32 toward the first electrode 31 is taken as down or below.

The semiconductor layer 10 is, for example, a silicon layer. In the semiconductor layer 10 in the specification, a first conductivity type is taken to be an n-type; and a second conductivity type is taken to be a p-type. The first conductivity type may be the p-type; and the second conductivity type may be the n-type.

The semiconductor layer 10 includes an n-type first semiconductor layer 11 located on the first electrode 31, and a p-type second semiconductor layer 12 located on the first semiconductor layer 11. The second semiconductor layer 12 contacts the first semiconductor layer 11; and the second semiconductor layer 12 and the first semiconductor layer 11 form a p-n junction 41. The second electrode 32 is located on the second semiconductor layer 12. The second semiconductor layer 12 contacts the second electrode 32 and is electrically connected with the second electrode 32.

The semiconductor layer 10 further includes an n-type third semiconductor layer 13 located between the first electrode 31 and the first semiconductor layer 11 in the second direction Z. The n-type impurity concentration of the third semiconductor layer 13 is greater than the n-type impurity concentration of the first semiconductor layer 11. The third semiconductor layer 13 contacts the first electrode 31 and is electrically connected with the first electrode 31.

The first semiconductor layer 11 is a drift layer of the diode; the second semiconductor layer 12 is an anode layer of the diode; and the third semiconductor layer 13 is a cathode layer of the diode.

The first semiconductor layer 11 includes a rare-earth element. The first semiconductor layer 11 includes, for example, a lanthanoid element as the rare-earth element. Examples of the lanthanoid element included in the first semiconductor layer 11 include erbium (Er) and thulium (Tm).

The first semiconductor layer 11 includes an impurity region 21, and a crystal defect region 22 that includes crystal defects. The concentration peak of the rare-earth element inside the first semiconductor layer 11 is in the impurity region 21. The density peak of the crystal defects inside the first semiconductor layer 11 is in the crystal defect region 22.

The impurity region 21 is positioned between the second semiconductor layer 12 and the crystal defect region 22 in the second direction Z. The impurity region 21 is positioned lower than the second semiconductor layer 12. In other words, the concentration peak of the rare-earth element is positioned lower than the p-n junction 41 between the second semiconductor layer 12 and the first semiconductor layer 11. The crystal defect region 22 that includes the density peak of the crystal defects is positioned between the impurity region 21 and the first electrode 31 in the second direction Z.

Crystal defects (stacking faults, dislocation defects, etc.) are present in the crystal defect region 22 at high density. The crystal defect region 22 functions as a lifetime control region because the crystal defects act as recombination centers of the carriers. When turning off the semiconductor device 1, the crystal defect region 22 promotes recombination of the carriers that are injected by the anode and remain in the first semiconductor layer 11 (the drift layer). As a result, the reverse recovery current is suppressed, and the quick reduction can reduce the switching loss.

According to the embodiment, as described below, the crystal defect region 22 can be locally formed at the necessary positions inside the first semiconductor layer 11. As a result, the switching loss can be reduced while suppressing the conduction loss of the diode.

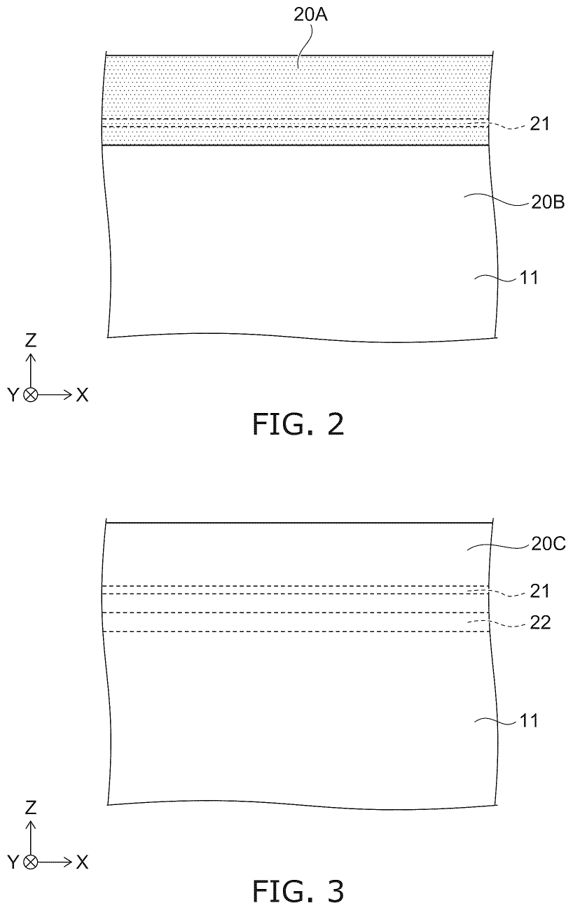

A method for manufacturing the semiconductor device 1 of the first embodiment will now be described with reference to FIGS. 2 to 4.

The method for manufacturing the semiconductor device 1 of the first embodiment includes a process of forming an amorphous region 20A in the first semiconductor layer 11 as shown in FIG. 2 by implanting a rare-earth element into the first semiconductor layer 11 (a silicon substrate). In FIG. 2, the amorphous region 20A is illustrated as a cross-hatched region. The impurity region 21 includes the concentration peak of the rare-earth element and is positioned at the vicinity of an average stopping depth Rp of the rare-earth element.

Er is ion-implanted through the surface of the first semiconductor layer 11 into a limited region by using, for example, an acceleration voltage of 500 keV and a dose of 1×10¹⁴ cm⁻². The silicon crystal of the first semiconductor layer 11 is amorphized in the region into which Er is implanted.

The rare-earth element is positioned at the lattice points in the silicon crystal with a stable 4-coordinate configuration. Rare-earth elements are not as heavy as noble metals, but are heavier than elements used to control the conductivity type of silicon. The crystal damage due to the ion implantation occurs when the implanted ions eject the silicon atoms from the lattice point. The silicon crystal is amorphized as more silicon atoms are ejected from the lattice positions. The amount of the ejected silicon atoms is greatly affected by the weight of the implanted element as well as ion implantation conditions such as the implantation amount, the acceleration voltage, etc. Elements such as B, P, etc., are light and therefore do not amorphize the silicon crystal in the implantation region; however, the silicon crystal is easily amorphized by ion-implanting a rare-earth element.

After forming the amorphous region 20A by ion-implanting a rare-earth element, the method for manufacturing the semiconductor device 1 of the first embodiment includes a first heat treatment process. The first heat treatment process crystallizes the amorphous region 20A and forms the crystal defect region 22 below a region 20C that is crystallized from the amorphous region 20A as shown in FIG. 3.

In the first heat treatment process, for example, heat treatment is performed for 30 minutes in a nitrogen (N₂) atmosphere at 950° C. As a result, the amorphous region 20A is recrystallized to form the region 20C that does not include crystal defects. Simultaneously, the crystal defect region 22 in which crystal defects are present at high density is formed below the boundary between the amorphous region 20A and a crystal region 20B that is under the amorphous region 20A and is not amorphized.

The interstitial silicon that is ejected by the ion implantation is diffused through the semiconductor layer by a subsequent heat treatment at about 1,000° C., generates crystal defects such as stacking faults, etc., and is stabilized. The region of the crystal defects formed after the heat treatment depends on whether or not the ion implantation region is amorphized. When not amorphized, crystal defects remain in a wide range in the depth direction (thickness direction of the semiconductor layer) around the average stopping depth Rp of the implanted ions. The amount of the crystal defects that remain is greatly affected by the heat treatment temperature; and the remaining crystal defect amount is low for temperatures of not less than 1,000° C.

On the other hand, when amorphizing by ion implantation is performed, the amorphous region 20A and the region 20B that is under the amorphous region 20A and remains in the crystalline state respectively become the region 20C, which is the amorphous region 20A recrystallized by the first heat treatment described above, and the crystal defect region 22; and the region 20C and the crystal defect region 22 are separated at the same boundary as the boundary between the amorphous region 20A and the region 20B. Excessive silicon atoms diffuse into a relatively narrow region of the region 20B, which remains as a crystal, that is deeper than the amorphous/crystal boundary, causing crystal defects to aggregate. The crystal defect amount in the crystal defect region 22 is affected by the heat treatment temperature, but once generated in the crystal defect region 22, the crystal defects are stable and substantially do not change.

According to the embodiment as described above, the amorphous region 20A can be easily formed by ion-implanting a heavy rare-earth element. As a result, the crystal defect region 22 can be locally formed in a region that is deeper than the average stopping depth Rp of the implanted ions. As a result, the switching loss can be reduced while suppressing the conduction loss of the diode.

The method for manufacturing the semiconductor device 1 of the first embodiment further includes a process of implanting a p-type impurity into the first semiconductor layer 11 after forming the crystal defect region 22, and a process of forming the p-type second semiconductor layer 12 positioned above the crystal defect region 22 as shown in FIG. 4 by a second heat treatment.

For example, the process of implanting the p-type impurity into the first semiconductor layer 11 includes ion-implanting B through the surface of the first semiconductor layer 11 into a limited region with an acceleration voltage of 70 keV and a dose of 1×10¹⁴ cm⁻². For example, in the second heat treatment process, heat treatment is performed for 30 minutes in a nitrogen (N₂) atmosphere at 950° C.

The method for manufacturing the semiconductor device 1 of the first embodiment includes a process of forming the second electrode 32 on the second semiconductor layer 12 after forming the second semiconductor layer 12.

After the second electrode 32 is formed, if necessary, the method for manufacturing the semiconductor device 1 of the first embodiment includes a process of forming the third semiconductor layer 13 and the first electrode 31 after thinning the first semiconductor layer 11 (the silicon substrate) by polishing the back surface of the first semiconductor layer 11 (the silicon substrate).

Although the first heat treatment after ion-implanting the rare-earth element and the second heat treatment after ion-implanting the p-type impurity are separately performed according to the embodiment above, the first heat treatment and the second heat treatment also can be simultaneously performed as the same heat treatment. The p-type impurity may be ion-implanted after ion-implanting the rare-earth element, or the rare-earth element may be ion-implanted after ion-implanting the p-type impurity. The second semiconductor layer 12 can be formed before ion-implanting the rare-earth element.

### Second Embodiment

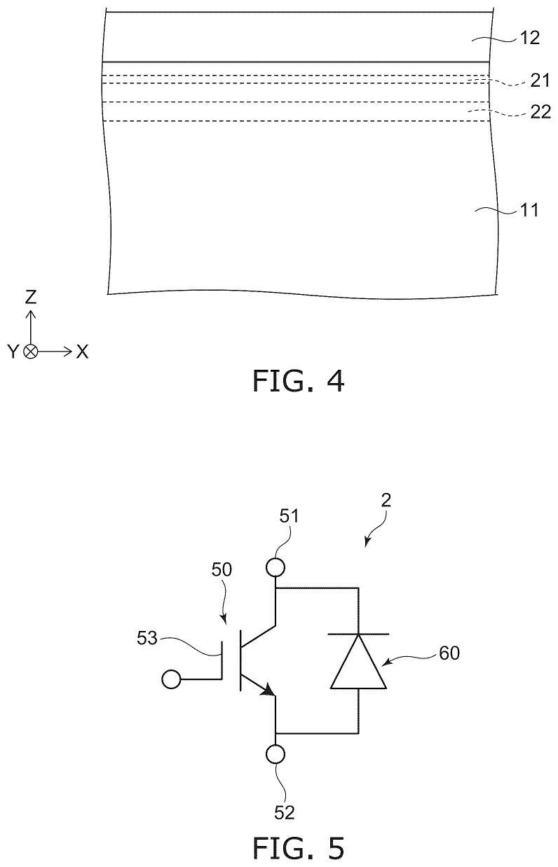

As shown in FIG. 5, the semiconductor device 2 of a second embodiment includes a transistor part 50 and a diode part 60. The semiconductor device 2 is, for example, an RC-IGBT in which the transistor part 50 and the diode part 60 are formed in the same semiconductor layer in one chip.

The transistor part 50 includes a collector electrode 51, an emitter electrode 52, and a gate electrode 53. The diode part 60 is connected in parallel with the transistor part 50. The anode of the diode part 60 is connected to the emitter electrode 52; and the cathode of the diode part 60 is connected to the collector electrode 51.

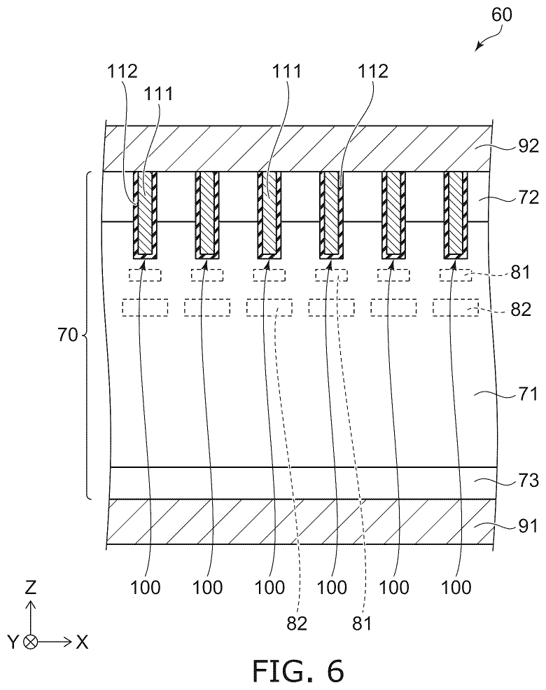

FIG. 6 is a schematic cross-sectional view of the diode part 60.

The diode part 60 includes a first electrode 91, a second electrode 92, and a semiconductor layer 70 located between the first electrode 91 and the second electrode 92 in the second direction Z. The first electrode 91 is the cathode electrode of the diode part 60, and is the collector electrode 51 of the transistor part 50. The second electrode 92 is the anode electrode of the diode part 60, and is the emitter electrode 52 of the transistor part 50. A current flows in the vertical direction (the second direction Z) between the first electrode 91 and the second electrode 92 via the semiconductor layer 70.

The semiconductor layer 70 is, for example, a silicon layer. The semiconductor layer 70 includes an n-type first semiconductor layer 71 located on the first electrode 91, and a p-type second semiconductor layer 72 located on the first semiconductor layer 71. The second semiconductor layer 72 contacts the first semiconductor layer 71; and the second semiconductor layer 72 and the first semiconductor layer 71 form a p-n junction. The second electrode 92 is located on the second semiconductor layer 72. The second semiconductor layer 72 contacts the second electrode 92 and is electrically connected with the second electrode 92.

The semiconductor layer 70 further includes an n-type third semiconductor layer 73 located between the first electrode 91 and the first semiconductor layer 71 in the second direction Z. The n-type impurity concentration of the third semiconductor layer 73 is greater than the n-type impurity concentration of the first semiconductor layer 71. The third semiconductor layer 73 contacts the first electrode 91 and is electrically connected with the first electrode 91.

In the transistor part 50, a p-type collector layer is located between the first electrode 91 and the first semiconductor layer 71.

The diode part 60 further includes multiple trench structure parts 100 that extend in the second direction Z from the surface of the semiconductor layer 70 and reach the first semiconductor layer 71. The multiple trench structure parts 100 are arranged in the first direction X and extend in the third direction Y. The second semiconductor layer 72 is positioned between the trench structure parts 100 adjacent to each other in the first direction X.

The trench structure part 100 includes a conductive member 111, and an insulating film 112 located between the conductive member 111 and the semiconductor layer 70. The upper end of the conductive member 111 is connected to the second electrode 92; and the conductive member 111 is electrically connected with the second electrode 92. The lower end of the trench structure part 100 and the lower end of the conductive member 111 are positioned lower than the p-n junction between the second semiconductor layer 72 and the first semiconductor layer 71. For example, polycrystalline silicon, a metal, etc., can be used as the material of the conductive member 111. The insulating film 112 is, for example, a silicon oxide film.

Similarly to the diode part 60, the transistor part 50 also includes the multiple trench structure parts 100. However, the conductive members 111 of the transistor part 50 are not connected with the second electrode 92, and function as the gate electrodes of the IGBT.

The first semiconductor layer 71 includes a rare-earth element. The first semiconductor layer 71 includes, for example, a lanthanoid element as the rare-earth element. Examples of the lanthanoid element included in the first semiconductor layer 71 include erbium (Er) and thulium (Tm).

The first semiconductor layer 71 includes an impurity region 81, and a crystal defect region 82 that includes crystal defects. The concentration peak of the rare-earth element inside the first semiconductor layer 71 is in the impurity region 81. The density peak of the crystal defects inside the first semiconductor layer 71 is in the crystal defect region 82.

In the second direction Z, the impurity region 81 is positioned between the trench structure part 100 and the crystal defect region 82 and between the second semiconductor layer 72 and the crystal defect region 82. The impurity region 81 is positioned lower than the second semiconductor layer 72. In other words, the concentration peak of the rare-earth element is positioned lower than the p-n junction between the second semiconductor layer 72 and the first semiconductor layer 71. The crystal defect region 82 that includes the density peak of the crystal defects is positioned between the impurity region 81 and the first electrode 91 in the second direction Z. In the drawings, the impurity regions 81 are not connected to each other in the first direction X, and the crystal defect region 82 are not connected to each other in the first direction X; however, the impurity regions 81 and the crystal defect regions 82 may be connected respectively and/or may respectively have concentration distributions in the first direction X.

The crystal defect region 82 promotes recombination of the carriers that are implanted by the anode and remain in the first semiconductor layer 71 (the drift layer) when turning off the semiconductor device 2. As a result, the reverse recovery current is suppressed, and the quick reduction can reduce the switching loss.

According to the embodiment as well, the crystal defect region 82 can be locally formed at the necessary position inside the first semiconductor layer 71. As a result, the switching loss can be reduced while suppressing the conduction loss of the diode.

In the example shown in FIG. 6, the crystal defect region 82 is positioned below the second semiconductor layer 72 in a region lower than the trench structure part 100 inside the first semiconductor layer 71 (not only in the region directly under the trench structure part 100, but also in a region below the second semiconductor layer 72). The crystal defect region 82 may be continuous in the first direction X in regions lower than the trench structure parts 100. Or, the crystal defect region 82 may be positioned in regions lower than the trench structure parts 100 that are only below the second semiconductor layer 72 but not positioned directly under the trench structure parts 100. Or, the crystal defect region 82 may be positioned between the trench structure parts 100 adjacent to each other in the first direction X.

The crystal defect region 82 makes it easier for carriers to efficiently recombine when positioned in a region lower than the trench structure parts 100 than when positioned between the trench structure parts 100.

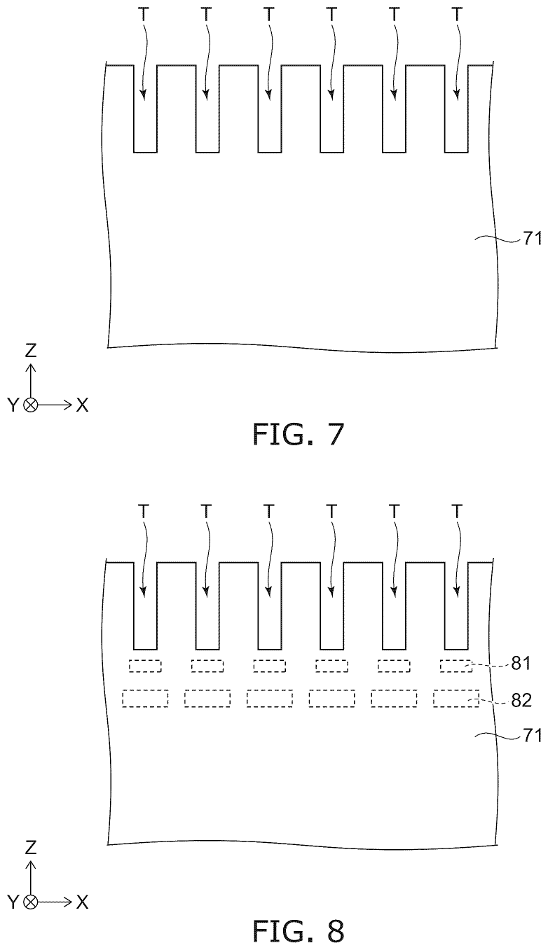

A method for manufacturing the semiconductor device 2 of the second embodiment will now be described with reference to FIGS. 7 and 8.

As shown in FIG. 7, multiple trenches T are formed in the first semiconductor layer 71 (the silicon substrate). The multiple trenches T are arranged in the first direction X and extend in the third direction Y. For example, the multiple trenches T can be formed by RIE (Reactive Ion Etching) using a mask of an interlayer film covering the first semiconductor layer 71 from above.

After forming the trenches T, the mask of the interlayer film covering the first semiconductor layer 71 from above is left as-is, and an amorphous region is formed in the first semiconductor layer 71 directly under the trenches T by implanting a rare-earth element into the first semiconductor layer 71 similarly to the first embodiment. Er is ion-implanted through the surface of the first semiconductor layer 71 into a limited region with, for example, an acceleration voltage of 70 keV and a dose of 1×10¹⁵ cm⁻². The silicon crystal of the first semiconductor layer 71 is amorphized in the region into which Er is implanted.

After forming the amorphous region, the first heat treatment is performed similarly to the first embodiment. The first heat treatment crystallizes the amorphous region and forms the crystal defect region 82 below the region crystallized from the amorphous region as shown in FIG. 8. The impurity region 81 that includes the concentration peak of the rare-earth element is positioned at the vicinity of the average stopping depth Rp of the rare-earth element.

According to the second embodiment as well, the amorphous region can be easily formed by ion-implanting a heavy rare-earth element. As a result, the crystal defect region 82 can be locally formed in a region that is deeper than the average stopping depth Rp of the implanted ions. As a result, the switching loss can be reduced while suppressing the conduction loss of the diode.

After forming the crystal defect region 82, for example, the insulating film 112 is formed at the inner wall of the trenches T the thermal oxidation. After forming the insulating film 112, the conductive member 111 is filled into the trenches T by, for example, CVD (Chemical Vapor Deposition).

Or, the formation of the amorphous region by ion-implanting the rare-earth element and the formation of the crystal defect region 82 by performing the first heat treatment may be performed after forming the insulating film 112 and the conductive member 111 inside the trenches T.

After forming the trench structure part including the insulating film 112 and the conductive member 111, similarly to the first embodiment, the formation continues with the process of forming the second semiconductor layer 72 by ion-implanting a p-type impurity and performing the second heat treatment, the process of forming the second electrode 92, the process of forming the third semiconductor layer 73, the process of forming the first electrode 91, etc.

Although Er is used as the rare-earth element according to the embodiments above, similar effects also are obtained when using another rare-earth element such as Tm, etc. The ion implantation conditions and the heat treatment conditions are presented as examples, and may be optimized. Although the crystal defect regions 22 and 82 are formed below the average stopping depth Rp of the implanted rare-earth element, the distances between the average stopping depth Rp and the crystal defect regions 22 and 82 are adjustable by the heat treatment conditions, etc., and may be within a range from the average stopping depth Rp and the crystal defect regions 22 and 82 being substantially in contact, up to being separated by about 1 μm.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a semiconductor layer located on the first electrode; and
a second electrode located on the semiconductor layer,
the semiconductor layer including
a first semiconductor layer including a rare-earth element, the first semiconductor layer being of a first conductivity type, and
a second semiconductor layer located on the first semiconductor layer and electrically connected with the second electrode, the second semiconductor layer contacting the first semiconductor layer, the second semiconductor layer being of a second conductivity type,
the first semiconductor layer including
an impurity region positioned between the second semiconductor layer and the first electrode, and
a crystal defect region positioned between the impurity region and the first electrode, the crystal defect region including crystal defects,
a concentration peak of the rare-earth element being in the impurity region.

2. The device according to claim 1, wherein
a density peak of the crystal defects is in the crystal defect region.

3. The device according to claim 1, wherein
the concentration peak of the rare-earth element is positioned lower than a junction between the second semiconductor layer and the first semiconductor layer.

4. The device according to claim 1, further comprising:
a plurality of trench structure parts reaching the first semiconductor layer from a surface of the semiconductor layer, the plurality of trench structure parts being arranged in a first direction,
the second semiconductor layer being positioned between the trench structure parts adjacent to each other in the first direction.

5. The device according to claim 4, wherein
the crystal defect region is positioned below the second semiconductor layer in a region lower than the trench structure part.

6. The device according to claim 4, wherein
the trench structure part includes a conductive member electrically connected with the second electrode.

7. The device according to claim 1, wherein
the rare-earth element is a lanthanoid element.

8. The device according to claim 7, wherein
the lanthanoid element is erbium or thulium.

9. A method for manufacturing a semiconductor device, the method comprising:
forming an amorphous region in a first semiconductor layer by implanting a rare-earth element into the first semiconductor layer, the first semiconductor layer being of a first conductivity type; and
crystallizing the amorphous region and forming a crystal defect region below the crystallized region by performing a first heat treatment.

10. The method according to claim 9, further comprising:
implanting a second-conductivity-type impurity into the first semiconductor layer before the implanting of the rare-earth element into the first semiconductor layer; and
forming a second semiconductor layer positioned above the crystal defect region by performing a second heat treatment, the second semiconductor layer being of a second conductivity type.

11. The method according to claim 9, further comprising:
implanting a second-conductivity-type impurity into the first semiconductor layer after the implanting of the rare-earth element into the first semiconductor layer; and
forming a second semiconductor layer positioned above the crystal defect region by performing a second heat treatment, the second semiconductor layer being of a second conductivity type.
